(19) United States
(12) Patent Application Publication
(10) Pub. No.: US 2016/0293383 A1
(43) Pub. Date: Oct. 6, 2016

(54) SPUTTERING DEVICE AND METHOD FOR REPLACING FILM ROLL IN SPUTTERING DEVICE

(71) Applicant: NITTO DENKO CORPORATION, Osaka (JP)

(72) Inventors: Tomotake Nashiki, Ibaraki-shi (JP); Akira Hamada, Ibaraki-shi (JP)

(73) Assignee: NITTO DENKO CORPORATION, Ibaraki-shi, Osaka (JP)

(21) Appl. No.: 15/025,825

(22) PCT Filed: Oct. 10, 2014
(86) PCT No.: PCT/JP2014/077187

§ 371 Date: Mar. 29, 2016

(30) Foreign Application Priority Data
Oct. 10, 2013 (JP) 2013-212497

(51) Int. Cl. H01J 37/32; C23C 14/56; H01J 37/34; C23C 14/34

(52) U.S. Cl. CPC H01J 37/3277; C23C 14/34; C23C 14/566; C23C 14/562; H01J 37/3417

(57) ABSTRACT

In a sputtering device, a supply-side film roll chamber includes a supply-side vacuum pump and a supply-side main valve. A storage-side film roll chamber includes a storage-side vacuum pump and a storage-side main valve. A supply-side load-lock valve is provided between the supply-side film roll chamber and a layer forming chamber. A storage-side load-lock valve is provided between the storage-side film roll chamber and the layer forming chamber. In a method for replacing a film roll, a supply-side main valve and a supply-side load-lock valve are closed when replacing a supply-side film roll. A storage side-main valve and a storage-side load-lock valve are closed when replacing a storage-side film roll.

### BACKGROUND OF THE INVENTION

1. Field of the Invention

The present invention relates to a sputtering device for continuously forming a thin layer on a film and a method for replacing a film roll in such a sputtering device.

2. Description of the Related Art

A sputtering method is widely used as a method for continuously forming a thin layer on a film. In a continuous sputtering device of a film, a layer forming roll and a target are placed oppositely at a predetermined interval. A layer forming roll wound around by a film in sputtering gas such as a low-pressure argon gas is referred to as an anode potential and a target is referred to as a cathode potential. A voltage is applied between the layer forming roll and the target to create a plasma in a sputtering gas. Sputtering gas ions in plasma collide with the target to knock out components of the target. The knocked out components of the target deposit on the film to form a thin layer.

In the case of a long film, it is impossible to form a sputtered layer over the whole of the long film at a time. Accordingly, the long film delivered from a supply-side film roll is wound around the layer forming roll (can roll) by less than one round, and the layer forming roll is rotated at a constant speed to cause the long film to run at a constant speed. A thin layer is deposited on a portion of the long film facing to the target. The long film after completion of thin layer deposition is wound to a storage-side wound core. Such a sputtering device is referred to as a roll-to-roll type sputtering device, a continuous sputtering device or a wind up sputtering device or the like.

In a roll-to-roll type sputtering device at an earlier time, a supply-side film roll chamber, a layer forming chamber, and a storage-side film roll chamber were not separated but were one vacuum chamber. When sputtering of one film roll was finished, the vacuum chamber was opened to replace a supply-side film roll and a storage-side film roll. After the film rolls were replaced, the vacuum chamber was closed to perform evacuation again. When a sufficient vacuum was obtained, sputtering of the film roll was conducted as below. In this method, every time the film roll is replaced, the vacuum chamber needs to be exposed to the air. This makes moisture in the air easily attach inside the vacuum chamber, which leads to need a long period of time to perform evacuation again. As a result, the roll-to-roll sputtering device has a low operation rate. As well known, moisture in the vacuum chamber is slower in discharge speed than the other gases (a nitrogen gas or an oxygen gas), resulting in major impediments to an increase of vacuum. Consequently, it is critical to avoid exposing the vacuum chamber to the air.

To solve this problem, for instance, in Japanese Unexamined Patent Application Publication No. JP 2003-183813 A, a vacuum chamber is divided into a supply-side film roll chamber, a layer forming chamber, a storage-side film roll chamber and a vacuum valve is provided between each chamber. Even when the supply-side film roll chamber and the storage-side film roll chamber are opened, vacuum in the layer forming chamber is maintained by closing a vacuum valve between each chamber when replacing a supply-side film roll and a storage-side film roll. While the layer forming chamber has a general vacuum pump, the supply-side film roll chamber and the storage-side film roll chamber also have a specific vacuum pump respectively. The supply-side film roll or the storage-side film roll is replaced and then the supply-side film roll chamber or the storage-side film roll chamber is evacuated by each vacuum pump. When a vacuum in the supply-side film roll chamber is the same as a vacuum in the layer forming chamber, a vacuum valve between the supply-side film roll chamber and the layer forming chamber is opened. And when a vacuum in the storage-side film roll chamber is the same as a vacuum in the layer forming chamber, a vacuum valve between the storage-side film roll chamber and the layer forming chamber is opened to subsequently perform sputtering. The use of this method enables to replace the supply-side film roll and the storage side-film roll without the exposure of the layer forming chamber to the air.

### PRIOR ART DOCUMENT

### Patent Document

Patent document 1: Japanese Unexamined Patent Application Publication No. JP 2003-183813 A

### SUMMARY OF THE INVENTION

Generally, to avoid contamination caused by oil, an oil-sealed rotary pump and an oil-diffusion pump are not used for a sputtering device. A dry pump (an oil free pump) such as a scroll pump or a turbo-molecular pump is used instead. Particularly, the turbo-molecular pump has a great evacuation velocity and can obtain a high vacuum, so that the turbo-molecular pump is suitable for a sputtering device. The turbo-molecular pump is, however, unable to evacuate the atmospheric pressure. Accordingly, evacuation is performed from the atmospheric pressure (about 10 [5] Pa) to about 1 Pa by a mechanical dry pump such as a scroll pump. And the configuration for evacuating from about 1 Pa to about 10[−5] Pa by using a turbo-molecular pump is widely used. 10^{X} indicates herein 10[X].

The turbo-molecular pump evacuates air by rotating blades thereof at ultra-high speed (for instance, 0.1 million rotations/minute). It takes a long time (for instance, 0.5 hour) for a large turbo-molecular pump to accelerate blades in a stopped state to an ultra-high speed. Further, it also takes a long time (for instance, 0.5 hour) to stop the blades rotating at ultra-high speed. As mentioned above, it needs extra time to switch on/off the turbo-molecular pump, so that it is preferable that the turbo-molecular pump is usually in a state of operation (ON).

A vacuum pump is preferably not exposed to the air. When the vacuum pump is exposed to the air, moisture enters inside the vacuum pump, resulting in deterioration of evacuation performance of the vacuum pump. Alternatively, this may cause a breakdown of the vacuum pump.

While JP 2003-183813 A fails to disclose the kind of vacuum pumps and an installation structure, in FIG. 1 in JP 2003-183813 A, each vacuum pump is directly coupled to a supply-side film roll chamber and a storage-side film roll chamber. Accordingly, in JP 2003-183813 A, when the supply-side film roll chamber or the storage-side film roll chamber is exposed to the air, each of the vacuum pumps is simultaneously exposed to the air. As a result, the vacuum pumps need to stop before the supply-side film roll chamber or the storage-side film roll chamber is exposed to the air. In addition, the vacuum pumps need to start up before evacuating the supply-side film roll chamber or the storage-side film roll chamber.

In the configuration of a sputtering device in JP 2003-183813 A, when a supply-side film roll or a storage-side film roll is replaced, there is a problem that it takes time to stop and start up the vacuum pumps other than the actual replacement. There is further a problem that evacuation performance of the vacuum pumps is deteriorated or the vacuum pumps break down due to the exposure of the vacuum pump to the air.

In recent years, film rolls have become greater in width and length, which leads to an increase of emitted gas (mainly moisture) from the film rolls. Emitted gas from a film roll is mixed in a sputtering gas in a layer forming chamber without sufficient evacuation of the film roll chamber, resulting in a decrease in sputtering layer quality. To prevent that, it is effective to evacuate the film roll chamber with a turbo-molecular pump which has a great evacuation speed and can obtain a high vacuum. The turbo-molecular pump, however, takes time to start-up and stop, so that it is preferable to continuously work (ON), avoiding switching on/off.

The present invention has the following objects:
(1) It is an object of the present invention to provide a sputtering device without the need to stop a supply-side vacuum pump when a supply-side film roll chamber is exposed to the air to replace a supply-side film roll.
(2) It is another object of the present invention to provide a sputtering device without the need to stop a storage-side vacuum pump when a storage-side film roll chamber is exposed to the air to replace a storage-side film roll.
(3) It is still another object of the present invention to provide a method for replacing a film roll without the need to stop a supply-side vacuum pump when replacing a supply-side film roll.
(4) It is a further object of the present invention to provide a method for replacing a film roll without the need to stop a storage-side vacuum pump when replacing a storage-side film roll.

The summary of the present invention is described as below.

In a first preferred aspect of the present invention, there is provided a sputtering device which includes: a supply-side film roll chamber including a film supplying apparatus; a supply-side vacuum pump configured to evacuate the supply-side film roll chamber; a supply-side main valve which can hermetically seal between the supply-side film roll chamber and the supply-side vacuum pump; a storage-side film roll chamber including a film storing apparatus; a storage-side vacuum pump configured to evacuate the storage-side film roll chamber; a storage-side main valve which is hermetically sealable between the storage-side film roll chamber and the storage-side vacuum pump; a layer forming chamber including a layer forming roll, at least one target facing to the layer forming roll, and at least one cathode to support the at least one target; a supply-side load-lock valve provided between the supply-side film roll chamber and the layer forming chamber; and a storage-side load-lock valve provided between the storage-side film roll chamber and the layer forming chamber.

In a second preferred aspect of the sputtering device according to the present invention, the supply-side vacuum pump and the storage-side vacuum pump are each a turbo-molecular pump.

In a third preferred aspect of the present invention, there is provided a method for replacing a film roll in a sputtering device of the present invention which includes the steps of:
(a) closing a supply-side main valve between a supply-side film roll chamber and a supply-side vacuum pump in a state of operating (ON) the supply-side vacuum pump to hermetically seal between the supply-side film roll chamber and the supply-side vacuum pump;
(b) closing a supply-side load-lock valve between the supply-side film roll chamber and a layer forming chamber in a state in which a film is penetrated through, leaving an end of the film in the supply-side film roll chamber to hermetically seal between the supply-side film roll chamber and the layer forming chamber;
(c) exposing the supply-side film roll chamber to the air;
(d) replacing a supply-side film roll to couple a tip of a new film to the end of the film;
(e) opening the supply-side main valve to evacuate the supply-side film roll chamber by use of the supply-side vacuum pump; and
(f) opening the supply-side load-lock valve to release the hermetic sealing between the supply-side film roll chamber and the layer forming chamber. Subsequently, ordinary sputtering is practicable.

In a fourth preferred aspect of the present invention, there is provided a method for replacing a film roll in the sputtering device of the present invention which includes the steps of:
(a) closing a storage-side main valve between a storage-side film roll chamber and a storage-side vacuum pump to hermetically seal between the storage-side film roll chamber and the storage-side vacuum pump;
(b) closing a storage-side load-lock valve between the storage-side film roll chamber and a layer forming chamber in a state in which a film is penetrated through to hermetically seal between the storage-side film roll chamber and the layer forming chamber;
(c) exposing the storage-side film roll chamber to the air;
(d) removing a storage-side film roll to couple the film to a film storing apparatus;
(e) opening the storage-side main valve to evacuate the storage-side film roll chamber by use of the storage-side vacuum pump; and
(f) opening the storage-side load-lock valve to release the hermetic sealing between the storage-side film roll chamber and the layer forming chamber. Subsequently, ordinary sputtering is practicable.

According to the sputtering device of the present invention, the following advantages are obtained:
(1) The supply-side load-lock valve is provided between the supply-side film roll chamber and the layer forming chamber. It is possible to hermetically seal the layer forming chamber by closing the supply-side load-lock valve. Once the supply-side load-lock valve is closed, a vacuum does not decrease even when the supply-side film roll chamber is exposed to the air.
(2) The storage-side load-lock valve is provided between the storage-side film roll chamber and the layer forming chamber. It is possible to hermetically seal the layer forming chamber by closing the storage-side load-lock valve. Once the storage-side load-lock valve is closed, vacuum in the layer forming chamber does not decrease even when the storage-side film roll chamber is exposed to the air.
(3) The supply-side main valve is provided between the supply-side film roll chamber and the supply-side vacuum pump. Once the supply-side main valve is closed, the supply-side vacuum pump is not exposed to the air even when the supply-side film roll chamber is exposed to the air. As a result, there is no need to stop (OFF) the supply-side vacuum pump.
(4) The storage-side main valve is provided between the storage-side film roll chamber and the storage-side vacuum pump. Once the storage-side main valve is closed, the storage-side vacuum pump is not exposed to the air even when the storage-side film roll chamber is exposed to the air. As a result, there is no need to stop (OFF) the storage-side vacuum pump.

According to the method for replacing a film roll of the sputtering device of the present invention, the following advantages are obtained:
(1) It is possible to replace the supply-side film roll without exposing the layer forming chamber to the air by closing the supply-side load-lock valve between the supply-side film roll chamber and the layer forming chamber. Since the layer forming chamber is not exposed to the air, it is possible to avoid time loss accompanied by the evacuation of the layer forming chamber. It is also possible to avoid contamination of the layer forming chamber.
(2) It is possible to replace a storage-side film roll without exposing the layer forming chamber to the air by closing the storage-side load-lock valve between the storage-side film roll chamber and the layer forming chamber. Since the layer forming chamber is not exposed to the air, it is possible to avoid time loss accompanied by the evacuation of the layer forming chamber. It is also possible to avoid contamination of the layer forming chamber.
(3) When the supply-side film roll is replaced, it is not needed to stop (OFF) the supply-side vacuum pump because the supply-side main valve is closed. Since the supply-side vacuum pump is not caused to stop, it is possible to avoid time loss caused by the stop and start-up of the supply-side vacuum pump. In addition, it is possible to prevent performance deterioration and breakdown because the supply-side vacuum pump is not exposed to the air.
(4) When the storage-side film roll is replaced, it is not needed to stop (OFF) the storage-side vacuum pump because the storage-side main valve is closed. Since the storage-side vacuum pump is not caused to stop, it is possible to avoid time loss caused by the stop and start-up of the storage-side vacuum pump. In addition, it is possible to prevent performance deterioration and breakdown because the storage-side vacuum pump is not exposed to the air.

### BRIEF DESCRIPTION OF THE DRAWING

FIG. 1 is a schematic view of a sputtering device of the present invention.

### DESCRIPTION OF THE PREFERRED EMBODIMENTS

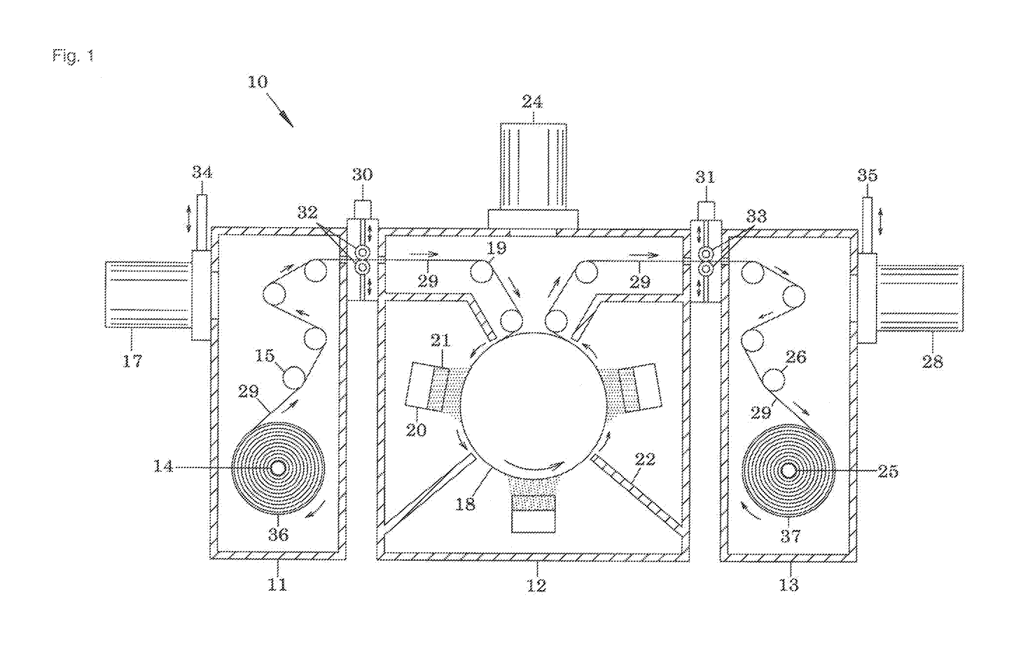

FIG. 1 is a schematic view of one example of a sputtering device 10 of the present invention. A sputtering device 10 of the present invention is divided broadly into a supply-side film roll chamber 11, a layer forming chamber 12, and a storage-side film roll chamber 13. The supply-side film roll chamber 11 includes a film supplying apparatus 14 and a plurality of guide rolls 15. A supply-side vacuum pump 17 is coupled to the supply-side film roll chamber 11 through a supply-side main valve 34. The layer forming chamber 12 includes a layer forming roll 18, a plurality of guide rolls 19, a plurality of cathodes 20, and a plurality of targets 21, and a plurality of walls 22. A layer forming chamber vacuum pump 24 is coupled to the layer forming chamber 12. The storage-side film roll chamber 13 includes a film storing apparatus 25 and a plurality of guide rolls 26. A storage-side vacuum pump 28 is coupled to the storage-side film roll chamber 13 through a storage-side main valve 35.

A film 29 is delivered from a supply-side film roll 36 to be guided by the plurality of guide rolls 15, 19 and wound around the layer forming roll 18 by less than one round and then to be rolled up to the film storing apparatus 25 by being guided again by the guide rolls 19, 26. Since each of the plurality of targets 21 are usually screwed on each of the plurality of cathodes 20, the targets 21 and the cathodes 20 are identical in potential. The targets 21 are usually a plural number (3 in FIG. 1) and are installed so as to surround the layer forming roll 18. The number of the target 21 may be one at the minimum and the maximum number of the targets 21 is not limited. A surface of each target 21 is opposed to the layer forming roll 18 at a predefined distance. A surface of each target 21 is parallel to a tangent of the layer forming roll 18. A sputtering thin layer is attached to the film 29 that continuously travels on the layer forming roll 18 in a position opposite to each target 21.

In a sputtering device 10 of the present invention, a layer forming roll 18 serves as an anode potential and a plurality of targets 21 each serve as a cathode potential in a sputtering gas such as a low-pressure argon gas to apply a voltage between the layer forming roll 18 and the plurality of targets 21. This creates a plasma of a sputtering gas between the film 29 and the targets 21. Sputtering gas ions in plasma collide with the targets 21 to knock out components of the targets 21. The knocked out components of the targets 21 deposit on the film 29 to form a thin layer.

A transparent film made of homopolymer or copolymer such as polyethylene terephthalate, polybuthylene terephthalate, polyamide, polyvinyl chloride, polycarbonate, polysthylene, polypropylene, and polyethylene may be generally used as a film 29. The film 29 may be a single film or may be a laminated film. The thickness of the film 29 is not particularly limited, but generally 6 μm to 250 μm.

For instance, a thin layer formed of an indium-tin-oxide (ITO) is widely used as a transparent conductive layer. The material of the targets 21 to be used for the sputtering device 10 of the present invention is, however, not particularly limited.

The material of the thin layer varies depending on the targets 21 and the sputtering gas may vary depending on the targets 21. Further, pressure may vary even when sputtering gases are identical. For instance, when a copper thin layer is deposited, a sputtering gas is an argon gas. When an indium-tin-oxide (ITO) is deposited, a sputtering gas is a mixed gas of an argon gas and an oxygen gas. As mentioned above, when the kind of gas and the pressure vary, the layer forming chamber 12 is separated by a plurality of walls 22.

In the sputtering device 10 of the present invention, a supply-side load-lock valve 30 is provided between the supply-side film roll chamber 11 and the layer forming chamber 12. Further, in the sputtering device 10 of the present invention, a storage-side load-lock valve 31 is provided between the layer forming chamber 12 and the storage-side film roll chamber 13. For instance, a plurality of supply-side roller gates 32 composed of two soft rollers that are opposed to each other are provided inside the supply-side load-lock valve 30. The plurality of supply-side roller gates 32 are not necessarily rollers but the shape thereof is not particularly limited as long as being flexible members which enable hermetic sealing with a film sandwiched between the supply-side roller gates 32. When the supply-side roller chamber 11 is exposed to the air, two rollers of the supply-side roller gates 32 are caused to adhere to each other to close the supply-side load-lock valve 30. This enables hermetic sealing between the supply-side film roll chamber 11 and the layer forming chamber 12. Even when the supply-side film roll chamber 11 is exposed to the air, it is possible to maintain the layer forming chamber 12 in a state of vacuum. At this time, it is possible to hermetically seal the supply-side load-lock valve 30, even in the state that the film 29 is sandwiched between the two rollers of the supply-side roller gates 32. The storage-side load-lock valve 31 includes a plurality of storage-side roller gates 33 composed of two soft rollers that are opposed to each other. As well as the supply-side load-lock valve 30, it is possible to hermetically seal the layer forming chamber 12 in a state that the film 29 is penetrated through the storage-side load-lock valve 31.

When the layer forming chamber 12 is exposed to the air to replace the plurality of targets 21 in the sputtering device 10 of the present invention, the following steps are taken: first, the supply-side load-lock valve 30 and the storage-side load-lock valve 31 are closed. Next, air is introduced into the layer forming chamber 12 so as to be one atmospheric pressure (to be exposed to the air). Next, replacement of the targets 21 is performed. Next, the layer forming chamber 12 is evacuated from one atmospheric pressure (about 10 [5] Pa) to about 1 Pa by a low-vacuum dry pump not shown (a scroll pump or the like). Next, the layer forming chamber 12 is evacuated from about 1 Pa to 10 [−5] Pa by the layer forming chamber vacuum pump 24 (a turbo-molecular pump or the like). Next, the supply-side load-lock valve 30 and the storage-side load-lock valve 31 are caused to open so that the film 29 may pass through. Next, a sputtering gas is introduced to reduce the evacuation velocity of the layer forming chamber vacuum pump 24 so that the pressure of the sputtering gas may be kept constant. Preparations for sputtering are completed by the above-mentioned steps.

It is extremely advantageous to be able to hermetically seal the supply-side load-lock valve 30 in a state that the film 29 is penetrated between the supply-side film roll chamber 11 and the layer forming chamber 12 when replacing a supply-side film roll 36. That is because the following method for replacing the supply-side film roll 36 becomes possible.

First, an end of the film 29 of the supply-side film roll 36 remains in the supply-side film roll chamber 11 and the plurality of supply-side roller gates 32 are closed, keeping the film 29 penetrating through the supply-side load-lock valve 30 to hermetically seal between the supply-side film roll chamber 11 and the layer forming chamber 12. Next, the supply-side main valve 34 is closed. Next, air is introduced into the supply-side film roll chamber 11 so as to be one atmospheric pressure. Next, the supply-side film roll 36 is replaced to couple a tip of the film 29 of a new supply-side film roll 36 to an end of the remaining film 29. Next, the supply-side film roll chamber 11 is evacuated by opening the supply-side main valve 34 to make the vacuum of the supply-side film roll chamber 11 similar to the vacuum of the layer forming chamber 12. Next, the supply-side roller gates 32 are opened so that the film 29 may freely pass through the supply-side load-lock valve 30. Next, the film 29 is wound up on the film storing apparatus 25 and then the film 29 in the supply-side film roll chamber 11, the layer forming chamber 12, and the storage-side film roll chamber 13 is automatically switched to the film 29 of the new supply-side film roll 36.

It involves extremely great efforts to hang the film 29 on the layer forming roll 18 and a large number of guide rolls 15, 19, and 26. In addition, the layer forming chamber 12 has to be exposed to the air. In that case, it takes extremely a long period of time to restore the original vacuum of the layer forming chamber 12 and restart sputtering. In the case where a method for replacing the film 29 employing the film 29 before the replacement is impracticable, it is needed to re-suspend the film 29 to the layer forming roll 18 and the large number of guide rolls 15, 19, 26 every time the supply-side film roll 36 is replaced. However, the sputtering device 10 of the present invention is capable of automatically hang the new film 29 on the layer forming roll 18 and the large number of guide rolls 15, 19, and 26 employing the film 29 before the replacement. Accordingly, it does not need time and efforts to replace the supply-side film roll 36. In addition, there is no need to expose the layer forming chamber 12 to the air.

In the sputtering device 10 of the present invention, the supply-side vacuum pump 17 is coupled to the supply-side film roll chamber 11 through the supply-side main valve 34. The supply-side vacuum pump 17 is typically a turbo-molecular pump. The supply-side main valve 34 is typically a gate valve. Once the supply-side main valve 34 is closed, even when the supply-side film roll chamber 11 is exposed to the air, the vacuum in the supply-side vacuum pump 17 is not affected.

The replacement of the supply-side film roll 36 is performed by the steps below. The supply-side vacuum pump 17 is in a state of constant operation (ON). That is, when the supply-side vacuum pump 17 is a turbo-molecular pump, blades are constantly rotating at ultra-high speed.

First, the supply-side main valve 34 is closed. This causes an inlet of the supply-side vacuum pump 17 to be hermetically sealed. Next, the supply-side roller gates 32 are closed with the end of the film 29 of the supply-side film roll 36 left in the supply-side film roll chamber 11 and then hermetic sealing is performed between the supply-side film roll chamber 11 and the layer forming chamber 12. At this time, the film 29 is being sandwiched between the supply-side roller gates 32. Next, the supply-side film roll chamber 11 is exposed to the air. Next, the supply-side film roll 36 is replaced and then the tip of the film 29 of a new supply-side film roll 36 is coupled to the end of the remaining film 29. Next, the supply-side film roll chamber 11 is evacuated by a low-vacuum pump not shown until the vacuum becomes about 1 Pa. Next, the supply-side main valve 34 is opened to evacuate the supply-side film roll chamber 11 by use of the supply-side vacuum pump 17 until the vacuum becomes about 10 [−5] Pa. This makes the vacuum of the supply-side film roll chamber similar to the vacuum of the layer forming chamber 12. Next, the supply-side roller gates 32 are opened to cause the film 29 to freely pass through the supply-side load-lock valve 30. When the film 29 is wound up on the film storing apparatus 25, the film 29 of the supply-side film roll chamber 11, the layer forming chamber 12, and the storage-side film roll chamber 13 are automatically switched to the film 29 of the new supply-side film roll 36. Subsequently, it is possible to perform sputtering as usual.

The replacement of a storage-side film roll 37 is performed by the steps below. The storage-side vacuum pump 28 constantly operates (ON). First, the storage-side main valve 35 is closed. This makes the inlet of the storage-side vacuum pump 28 to be hermetically sealed. Next, the storage-side roller gates 33 included in the storage-side load-lock valve 31 are closed to hermetically seal between the storage-side film roll chamber 13 and the layer forming chamber 12. At this time, the film 29 is in a state of being sandwiched between the storage-side roller gates 33 included in the storage-side load-lock valve 31. Next, the storage-side film roll chamber 13 is exposed to the air. Next, the film 29 in the storage-side film roll chamber 13 is cut. Next, the storage-side film roll 37 is taken out. Next, a tip of the film 29 is coupled to the film storing apparatus 25. Next, the storage-side film roll chamber 13 is evacuated by a low-vacuum pump not shown until the vacuum in the storage-side film roll chamber 13 becomes about 1 Pa. Next, the storage-side main valve 35 is opened to evacuate the storage-side film roll chamber 13 by use of the storage-side vacuum pump 28 until the vacuum becomes about 10 [−5] Pa. This makes the vacuum of the storage-side film roll chamber 13 similar to the vacuum of the layer forming chamber 12. Next, the storage-side roller gates 33 included in the storage-side load-lock valve 31 between the storage-side film roll chamber 13 and the layer forming chamber 12 are opened to enable the film 29 to freely pass through the storage-side load-lock valve 31. After that, it is possible to perform sputtering as usual. In the case where replacement of the supply-side film roll 36 is conducted at the same time when the storage-side film roll 37 is replaced, stop time is short, resulting in little reduction in operation rate.

### INDUSTRIAL APPLICABILITY

The sputtering device and the method for replacing a film roll in the sputtering device of the present invention are useful for sputtering each kind of a thin layer on a long film.

What is claimed is:

1. A sputtering device, comprising:
a supply-side film roll chamber including a film supplying apparatus;
a supply-side vacuum pump configured to evacuate the supply-side film roll chamber;
a supply-side main valve that hermetically seals between the supply-side film roll chamber and the supply-side vacuum pump;
a storage-side film roll chamber including a film storing apparatus;
a storage-side vacuum pump configured to evacuate the storage-side film roll chamber;
a storage-side main valve that hermetically seals between the storage-side film roll chamber and the storage-side vacuum pump;
a layer forming chamber including a layer forming roll, at least one target facing to the layer forming roll, and at least one cathode to support the at least one target;
a supply-side load-lock valve provided between the supply-side film roll chamber and the layer forming chamber; and
a storage-side load-lock valve provided between the storage-side film roll chamber and the layer forming chamber.

2. The sputtering device according to claim 1, wherein the supply-side vacuum pump and the storage-side vacuum pump are each a turbo-molecular pump.

3. A method for replacing a film roll in a sputtering device, comprising the steps of:
closing a supply-side main valve between a supply-side film roll chamber and a supply-side vacuum pump in a state of operating (ON) the supply-side vacuum pump to hermetically seal between the supply-side film roll chamber and the supply-side vacuum pump;
closing a supply-side load-lock valve between the supply-side film roll chamber and a layer forming chamber in a state in which a film is penetrated through, leaving an end of the film in the supply-side film roll chamber to hermetically seal between the supply-side film roll chamber and the layer forming chamber;
exposing the supply-side film roll chamber to the air;
replacing a supply-side film roll to couple a tip of a new film to the end of the film;
opening the supply-side main valve to evacuate the supply-side film roll chamber by use of the supply-side vacuum pump; and
opening the supply-side load-lock valve to release the hermetic sealing between the supply-side film roll chamber and the layer forming chamber.

4. A method for replacing a film roll in a sputtering device, comprising the steps of:
closing a storage-side main valve between a storage-side film roll chamber and a storage-side vacuum pump to hermetically seal between the storage-side film roll chamber and the storage-side vacuum pump;
closing a storage-side load-lock valve between the storage-side film roll chamber and a layer forming chamber in a state in which a film is penetrated through to hermetically seal between the storage-side film roll chamber and the layer forming chamber;
exposing the storage-side film roll chamber to the air;
removing a storage-side film roll to couple the film to a film storing apparatus;
opening the storage-side main valve to evacuate the storage-side film roll chamber by use of the storage-side vacuum pump; and
opening the storage-side load-lock valve to release the hermetic sealing between the storage-side film roll chamber and the layer forming chamber.
